(19) United States
(12) Patent Application Publication
(10) Pub. No.: US 2026/0208348 A1
(43) Pub. Date: Jul. 23, 2026

(54) ROBOT FOR USE IN VACUUM ENVIRONMENT

(71) Applicant: KAWASAKI JUKOGYO KABUSHIKI KAISHA, Kobe-shi, Hyogo (JP)

(72) Inventors: Ryota ONO, Kobe-shi (JP); Takeshi SHIBATA, Kobe-shi (JP)

(73) Assignee: KAWASAKI JUKOGYO KABUSHIKI KAISHA, Kobe-shi, Hyogo (JP)

(21) Appl. No.: 19/142,808

(22) PCT Filed: Dec. 28, 2023
(86) PCT No.: PCT/JP2023/047328

§ 371 Date: Jun. 24, 2025

(30) Foreign Application Priority Data
Dec. 28, 2022 (JP) 2022-211564

(51) Int. Cl. B25J 9/00; B25J 9/10; B25J 9/16; B25J 19/00

(52) U.S. Cl. CPC B25J 9/0087; B25J 9/104; B25J 9/1692; B25J 19/0054; B25J 19/0075

(57) ABSTRACT

In a robot (100) for use in a vacuum environment, a drive (30) is configured to drive a plurality of arm units (10) connected to each other in conjunction with each other such that a robot arm (1) operates to move a hand (13) within a circular range in a horizontal plane. An interior (1b) of the robot arm (1) is at atmospheric pressure.

### TECHNICAL FIELD

The present disclosure relates to a robot for use in a vacuum environment.

### BACKGROUND ART

Conventionally, a robot for use in a vacuum environment, including a robot arm that operates to move a hand within a circular range is known. For example, Japanese Patent No. 6951691 discloses a robot for use in a vacuum environment, including a robot arm including a base link that rotates relative to a base, an intermediate link that rotates relative to the base link, and a hand that supports a substrate and rotates relative to the intermediate link. The robot arm operates such that the base link, the intermediate link, and the hand rotate in conjunction with each other to move the hand within a circular range. The robot arm is used in a vacuum environment. The internal space of a motor that drives the robot arm is in a vacuum state. The internal space of the robot arm is directly connected to the internal space of the motor.

### PRIOR ART

### Patent Document

Patent Document 1: Japanese Patent No. 6951691

### SUMMARY OF THE INVENTION

However, in the robot for use in a vacuum environment described in Japanese Patent No. 6951691, the internal space of the robot arm is directly connected to the internal space of the motor in a vacuum state. Therefore, although not clearly described in Japanese Patent No. 6951691, in the robot for use in a vacuum environment described in Japanese Patent No. 6951691, the interior of the robot arm is conceivably in a vacuum state. In a conventional robot for use in a vacuum environment, such as that described in Japanese Patent No. 6951691, the robot arm becomes hot due to the high temperature of the substrate, and when the interior of the robot arm is in a vacuum state, heat is less likely to be dissipated from the robot arm because heat transfer by convection does not occur in the vacuum. In such a case, for example, it is necessary to provide water-cooling piping or the like inside the robot arm in order to cool the robot arm, and thus the device configuration of the robot arm becomes complex. Therefore, there is a demand for a robot for use in a vacuum environment that can improve the heat dissipation of a robot arm that operates to move a hand within a circular range while reducing or preventing the complexity of the device configuration.

The present disclosure is intended to solve the above problems. The present disclosure aims to provide a robot for use in a vacuum environment capable of improving the heat dissipation of a robot arm that operates to move a hand within a circular range while reducing or preventing the complexity of the device configuration.

In order to attain the aforementioned object, a robot for use in a vacuum environment according to an aspect of the present disclosure includes a hand to support a substrate, a horizontal articulated robot arm to allow the hand to be attached thereto and including a plurality of arm units for use inside a vacuum chamber, the plurality of arm units being connected to each other, and a drive to drive the robot arm. The drive is configured to drive the plurality of arm units connected to each other in conjunction with each other such that the robot arm operates to move the hand within a circular range in a horizontal plane, and an interior of the robot arm is at atmospheric pressure.

In the robot for use in a vacuum environment according to this aspect of the present disclosure, as described above, the drive is configured to drive the plurality of arm units connected to each other in conjunction with each other such that the robot arm operates to move the hand within the circular range in the horizontal plane. The interior of the robot arm is at atmospheric pressure. Accordingly, heat from the robot arm can be dissipated through air in the interior of the robot arm. That is, in the robot arm that operates to move the hand within the circular range, the heat from the robot arm can be dissipated without providing water cooling piping or the like in the interior of the robot arm, unlike a case in which the interior of the robot arm is in a vacuum state. Consequently, the heat dissipation of the robot arm that operates to move the hand within the circular range can be improved while the complexity of the device configuration is reduced or prevented.

According to the present disclosure, as described above, it is possible to provide the robot for use in a vacuum environment capable of improving the heat dissipation of the robot arm that operates to move the hand within the circular range while reducing or preventing the complexity of the device configuration.

### BRIEF DESCRIPTION OF THE DRAWINGS

FIG. 1 is a plan view showing a robot for use in a vacuum environment and a vacuum chamber according to an embodiment of the present disclosure.

FIG. 2 is a perspective view showing the overall configuration of the robot for use in a vacuum environment according to the embodiment of the present disclosure.

FIG. 3 is a sectional view showing the vicinity of a first rotation shaft that is a rotation shaft of a first arm unit of the robot for use in a vacuum environment according to the embodiment of the present disclosure.

FIG. 4 is a sectional view showing the vicinity of a second rotation shaft that is a rotation shaft of a second arm unit of the robot for use in a vacuum environment according to the embodiment of the present disclosure.

FIG. 5 is a sectional view showing the vicinity of a third rotation shaft that is a rotation shaft of a hand of the robot for use in a vacuum environment according to the embodiment of the present disclosure.

FIG. 6 is a sectional view for illustrating removal of a robot arm of the robot for use in a vacuum environment from a base according to the embodiment of the present disclosure.

### MODES FOR CARRYING OUT THE INVENTION

An embodiment embodying the present disclosure is hereinafter described on the basis of the drawings.

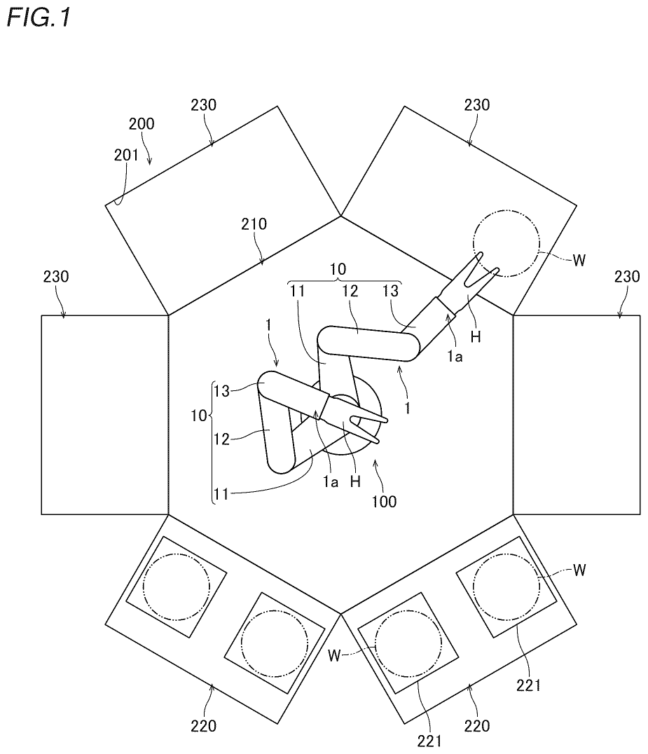

The configuration of a robot 100 for use in a vacuum environment according to the embodiment of the present disclosure is now described with reference to FIGS. 1 to 6.

### Overall Configuration of Robot for Use in Vacuum Environment

As shown in FIG. 1, the robot 100 for use in a vacuum environment is a robot 100 for use in a vacuum environment in which a plurality of arm units 10 of robot arms 1 are used in a space 201 inside a vacuum chamber 200. The robot 100 for use in a vacuum environment is a robot including the plurality of arm units 10 to transport substrates W within the space 201 inside the vacuum chamber 200.

The vacuum chamber 200 includes a transport chamber 210, cassette chambers 220, and processing chambers 230. The robot arms 1 are arranged inside the transport chamber 210. The cassette chambers 220 and the processing chambers 230 are provided around the transport chamber 210 so as to be adjacent to each other. Cassettes 221 storing the substrates W are arranged inside the cassette chambers 220. In the processing chambers 230, a predetermined process such as a heat treatment is performed on the substrate W. The robot arms 1 transport the substrates W between the cassette chambers 220 and the processing chambers 230 via the transport chamber 210.

In the following description, the upward-downward direction of the robot 100 for use in a vacuum environment is defined as a Z direction, and the upper and lower sides of the robot 100 for use in a vacuum environment are defined as a Z1 side and a Z2 side, respectively.

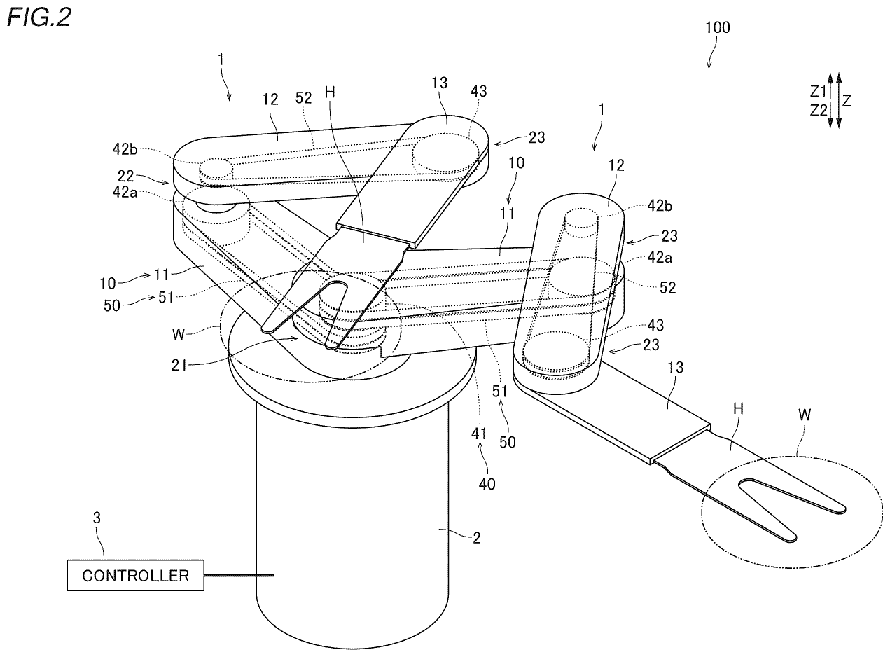

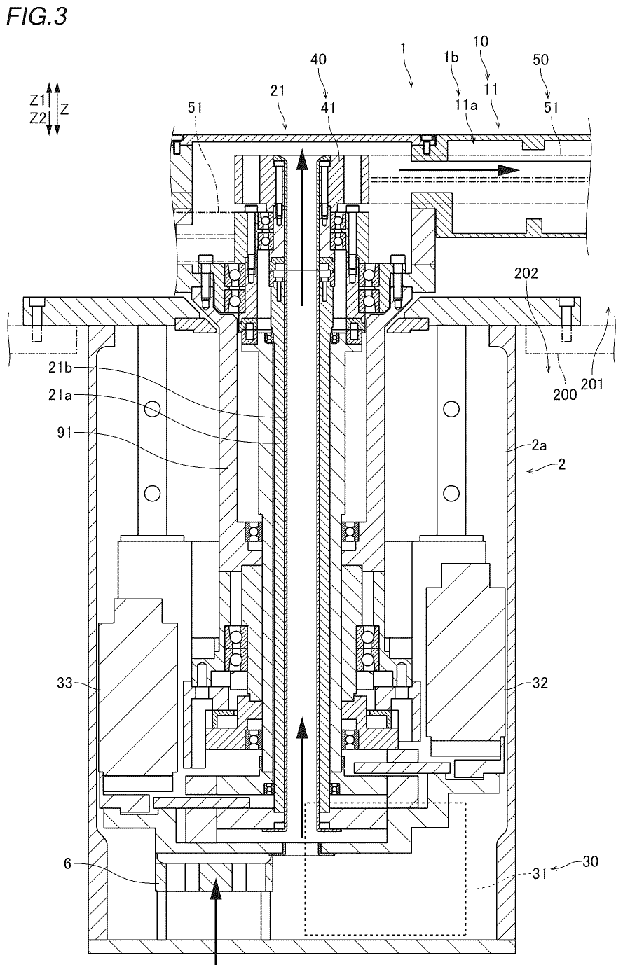

As shown in FIG. 2, the robot 100 for use in a vacuum environment includes two robot arms 1, a base 2, and two hands H. That is, the robot 100 for use in a vacuum environment is a dual-arm robot. As shown in FIG. 1, a plurality of arm units 10 of each of the two robot arms 1 are arranged in the space 201 inside the vacuum chamber 200. The two hands H are arranged in the space 201 inside the vacuum chamber 200. As shown in FIG. 3, the base 2 is arranged in a space 202 outside the vacuum chamber 200. As shown in FIG. 1, the two robot arms 1 have similar structures to each other.

As shown in FIG. 2, the robot arms 1 are horizontal articulated robot arms in which a plurality of arm units 10 are connected to each other. Specifically, each of the robot arms 1 includes, as the arm units 10, a first arm unit 11, a second arm unit 12, and a hand unit 13. The first arm unit 11, the second arm unit 12, and the hand unit 13 extend within a horizontal plane.

As shown in FIG. 3, the first arm unit 11 is supported by the base 2 from the Z2 side. That is, the base 2 supports the robot arms 1 from the Z2 side. A proximal portion of the first arm unit 11 is connected to the base 2 via a first joint 21. The first joint 21 includes a first rotation shaft 91 extending in the Z direction. The first arm unit 11 is rotatable relative to the base 2 around the first rotation shaft 91 in the horizontal plane.

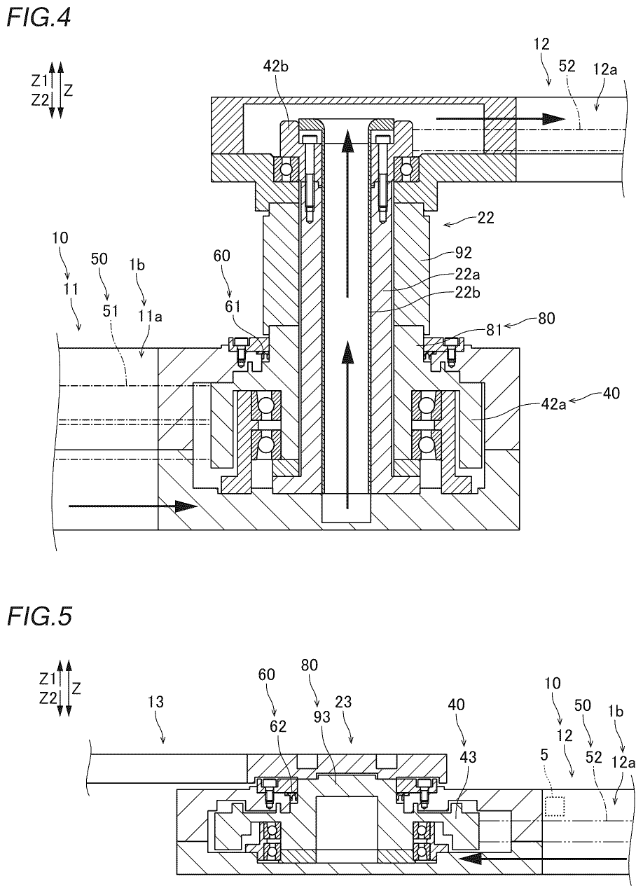

As shown in FIG. 4, the second arm unit 12 is supported by the first arm unit 11 from the Z2 side. A proximal portion of the second arm unit 12 is connected to a distal portion of the first arm unit 11 via a second joint 22. The second joint 22 includes a second rotation shaft 92 extending in the Z direction. The second arm unit 12 is rotatable relative to the first arm unit 11 around the second rotation shaft 92, which is different from the first rotation shaft 91, in the horizontal plane.

As shown in FIG. 5, the hand unit 13 is supported by the second arm unit 12. A proximal portion of the hand unit 13 is connected to a distal portion of the second arm unit 12 via a third joint 23. The third joint 23 includes a third rotation shaft 93 extending in the Z direction. The hand unit 13 is rotatable relative to the second arm unit 12 around the third rotation shaft 93, which is different from the first rotation shaft 91 and the second rotation shaft 92, in the horizontal plane. The third rotation shaft 93 is an example of a second rotating member.

As shown in FIG. 1, the hands H are attached to distal ends of the hand units 13. The hands H support the substrates W. That is, the hands H that support the substrates W are attached to distal ends 1a of the robot arms 1.

As shown in FIG. 3, the robot 100 for use in a vacuum environment includes a drive 30. The drive 30 drives the robot arms 1. The drive 30 is arranged in the interior 2a of the base 2. In other words, the drive 30 is arranged in the space 202 outside the vacuum chamber 200.

As shown in FIG. 2, the robot 100 for use in a vacuum environment includes a controller 3. The controller 3 controls the operation of the robot arms 1 by controlling the drive 30 (see FIG. 3). The controller 3 is arranged in the space 202 (see FIG. 3) outside the vacuum chamber 200 (see FIG. 3). The controller 3 may be arranged outside the base 2 or may be arranged in the interior 2a of the base 2. The controller 3 is an example of a cooling controller.

### Details of Operation of Robot Arm

As shown in FIG. 1, the drive 30 (see FIG. 3) drives the plurality of arm units 10 connected to each other in conjunction with each other such that the robot arms 1 operate to move the hands H within a circular range in the horizontal plane. That is, the robot arms 1 operate to transport the substrates W supported by the hands H between the cassette chambers 220 and the processing chambers 230 arranged around the transport chamber 210 via the transport chamber 210. As shown in FIG. 2, the robot arms 1 each include a pulley 40 and a belt 50 that transmit the driving force of the drive 30 such that the drive 30 (see FIG. 3) causes the plurality of arm units 10 connected to each other to operate in conjunction with each other. The pulley 40 and the belt 50 are arranged in the interior 1b of the robot arm 1.

Specifically, as shown in FIG. 3, the drive 30 includes a first drive 31 to rotate the first arm unit 11 of each of the two robot arms 1, a second drive 32 to rotate the second arm unit 12 (see FIG. 2) and the hand unit 13 (see FIG. 2) of one of the two robot arms 1 in conjunction with each other, and a third drive 33 to rotate the second arm unit 12 and hand unit 13 of the other of the two robot arms 1 in conjunction with each other.

The driving force of the first drive 31 is transmitted to the first rotation shaft 91 of the first joint 21 via a driving force transmission mechanism such as a gear. The first rotation shaft 91 is fixed to the first arm unit 11 of each of the two robot arms 1. Thus, driving of the first drive 31 causes the first arm unit 11 of each of the two robot arms 1 to rotate around the first rotation shaft 91 in the horizontal plane.

The driving force of the second drive 32 is transmitted to an inner rotation shaft 21a arranged inside the first rotation shaft 91 of the first joint 21 via a driving force transmission mechanism such as a gear. The pulley 40 includes a first joint-side pulley 41. The first joint-side pulley 41 is arranged in the interior 11a of the first arm unit 11 and arranged around the first rotation shaft 91. The first joint-side pulley 41 is fixed to the inner rotation shaft 21a of the first joint 21. The belt 50 includes a first arm inner belt 51. The first arm inner belt 51 is arranged in the interior 11a of the first arm unit 11 of one of the two robot arms 1. The first joint-side pulley 41 is connected to the first arm inner belt 51.

As shown in FIG. 4, the pulley 40 includes a second joint-side lower pulley 42a. The second joint-side lower pulley 42a is arranged in the interior 11a of the first arm unit 11 and arranged around the second rotation shaft 92. The second joint-side lower pulley 42a is arranged on the Z2 side at the second joint 22. The first arm inner belt 51 is connected to the second joint-side lower pulley 42a at the second joint 22. The second joint-side lower pulley 42a is an example of a first pulley.

The second joint-side lower pulley 42a is fixed to the second rotation shaft 92 of the second joint 22 and an inner rotation shaft 22a arranged inside the second rotation shaft 92. The second rotation shaft 92 and the inner rotation shaft 22a of the second joint 22 rotate independently of each other. The second rotation shaft 92 is fixed to the second arm unit 12 on the Z1 side of the second joint 22. Thus, driving of the second drive 32 causes the second arm unit 12 of one of the two robot arms 1 to rotate around the second rotation shaft 92 in the horizontal plane.

The pulley 40 includes a second joint-side upper pulley 42b. The second joint-side upper pulley 42b is arranged in the interior 12a of the second arm unit 12 and arranged around the second rotation shaft 92. The second joint-side upper pulley 42b is arranged on the Z1 side at the second joint 22. The inner rotation shaft 22a of the second joint 22 is fixed to the second joint-side upper pulley 42b. The belt 50 includes a second arm inner belt 52. The second arm inner belt 52 is arranged in the interior 12a of the second arm unit 12. The second arm inner belt 52 is connected to the second joint-side upper pulley 42b.

As shown in FIG. 5, the pulley 40 includes a third joint-side pulley 43. The third joint-side pulley 43 is arranged in the interior 11a of the second arm inner belt 52 and arranged around the third rotation shaft 93. The second arm inner belt 52 is connected to the third joint-side pulley 43 at the third joint 23. The third joint-side pulley 43 is integrally formed with the third rotation shaft 93 of the third joint 23, as described below. The third rotation shaft 93 of the third joint 23 is fixed to the hand unit 13. Thus, driving of the second drive 32 causes the hand unit 13 of one of the two robot arms 1 to rotate around the third rotation shaft 93 in the horizontal plane. The third joint-side pulley 43 is an example of a second pulley.

As described above, the driving of the second drive 32 causes the second arm unit 12 of one of the two robot arms 1 to rotate around the second rotation shaft 92 in the horizontal plane, and causes the hand unit 13 of one of the two robot arms 1 to rotate around the third rotation shaft 93 in the horizontal plane. The controller 3 (see FIG. 1) controls driving of the first drive 31 (see FIG. 3) for rotating the first arm unit 11 (see FIG. 3) so as to be linked with driving of the second drive 32 (see FIG. 3) for rotating the second arm unit 12 and the hand unit 13 in one of the two robot arms 1. Accordingly, the position of the hand unit 13 moves within the circular range. The structure for rotating the second arm unit 12 and hand unit 13 of the other of the two robot arms 1 in conjunction with each other by the third drive 33 is substantially the same as the structure for rotating the second arm unit 12 and hand unit 13 of one of the two robot arms 1 in conjunction with each other by the second drive 32, and thus a description thereof is omitted.

### Sealing Structure of Robot Arm

As shown in FIG. 3, the interior 1b of the robot arm 1 is at atmospheric pressure. In addition to the interior 1b of the robot arm 1, the interior 2a of the base 2 is also at atmospheric pressure. Specifically, the base 2 is arranged in the space 202 outside the vacuum chamber 200 and is not sealed, and thus the interior 2a of the base 2 is at atmospheric pressure. The base 2 is connected to the first arm unit 11 via the interior of a hollow first shaft 21b provided inside the inner rotation shaft 21a of the first joint 21. As shown in FIG. 4, the first arm unit 11 is connected to the second arm unit 12 via the interior of a hollow second shaft 22b provided inside the inner rotation shaft 22a of the second joint 22. Thus, the interiors of the first arm unit 11, the second arm unit 12 and the base 2 are at atmospheric pressure.

The robot arm 1 includes a rotating member 70 formed integrally with the pulley 40. The robot arm 1 also includes a seal 60 that provides a seal between the arm units 10 and the rotating member 70 to maintain the interior 1b of the robot arm 1 at atmospheric pressure. The seal 60 is fixed to the arm units 10 so as to rotate together with the arm units 10.

Specifically, the rotating member 70 includes a first rotating member 71 formed integrally with the second joint-side lower pulley 42a. The first rotating member 71 is arranged in the interior 11a of the first arm unit 11. The seal 60 includes a first seal 61. The first seal 61 is arranged in the interior 11a of the first arm unit 11. The first seal 61 is fixed to the first arm unit 11 so as to rotate together with the first arm unit 11. The first seal 61 is a contact seal.

As shown in FIG. 5, the rotating member 70 includes the third rotation shaft 93 formed integrally with the third joint-side pulley 43. The third rotation shaft 93 is arranged in the interior 12a of the second arm unit 12. The seal 60 includes a second seal 62. The second seal 62 is arranged in the interior 12a of the second arm unit 12. The second seal 62 is fixed to the second arm unit 12 so as to rotate together with the second arm unit 12. The second seal 62 is a contact seal.

### Heat Dissipation of Robot Arm

The belt 50 is made of a material having a thermal expansion coefficient different from those of the plurality of arm units 10. The plurality of arm units 10 are made of aluminum, for example. The belt 50 is made of steel, for example. In such a case, the expansion coefficient of the belt 50 is smaller than the thermal expansion coefficient of the robot arm 1. Therefore, when the robot arm 1 becomes hot, the ratio of the size of the plurality of arm units 10 of the robot arm 1 to the size of the belt 50 becomes different from that when the robot arm 1 is at room temperature. Accordingly, the operating accuracy of the robot arm 1 decreases. Therefore, it may be necessary to dissipate heat from the robot arm 1.

Therefore, the robot 100 for use in a vacuum environment includes a temperature sensor 5 that measures the temperature of the interior 1b of the robot arm 1. That is, the robot 100 for use in a vacuum environment includes the temperature sensor 5 that serves as a sensor provided in the interior 1b of the robot arm 1 to detect the state of the robot arm 1. The temperature sensor 5 is arranged in the interior 1b of the robot arm 1. Although the figure shows an example in which only one temperature sensor 5 is provided in a distal portion of the second arm unit 12, the temperature sensor 5 may be provided in another portion of the second arm unit 12 or may be provided in the first arm unit 11 (see FIG. 3), or a plurality of temperature sensors may be provided.

The controller 3 (see FIG. 2) performs a control to cool the interior 1b of the robot arm 1 based on the measurement result of the temperature sensor 5. Specifically, as shown in FIG. 3, the base 2 includes a fan 6 to take in air from outside the base 2. In addition, air discharge piping (not shown) is provided at a distal end of the robot arm 1. The controller 3 (see FIG. 2) performs a control to drive the fan 6 when the temperature measured by the temperature sensor 5 (see FIG. 5) is a temperature at which the interior 1b of the robot arm 1 needs to be cooled. When the fan 6 is driven, air taken in from outside the base 2 to the interior 2a of the base 2 is supplied to the first arm unit 11 through the interior of the first shaft 21b provided at the first joint 21. In addition, as shown in FIG. 4, the air supplied to the first arm unit 11 is supplied to the second arm unit 12 through the interior of the second shaft 22b provided at the second joint 22. The air supplied to the second arm unit 12 is discharged to the exterior of the robot arm 1 from the air discharge piping. The controller 3 (see FIG. 2) performs a control to stop driving of the fan 6 (see FIG. 3) when the temperature measured by the temperature sensor 5 (see FIG. 5) is a temperature at which the interior 1b of the robot arm 1 does not need to be cooled. The controller 3 may adjust the amount of air taken in by the fan 6 based on the temperature measured by the temperature sensor 5.

### Removal of Robot Arm From Base

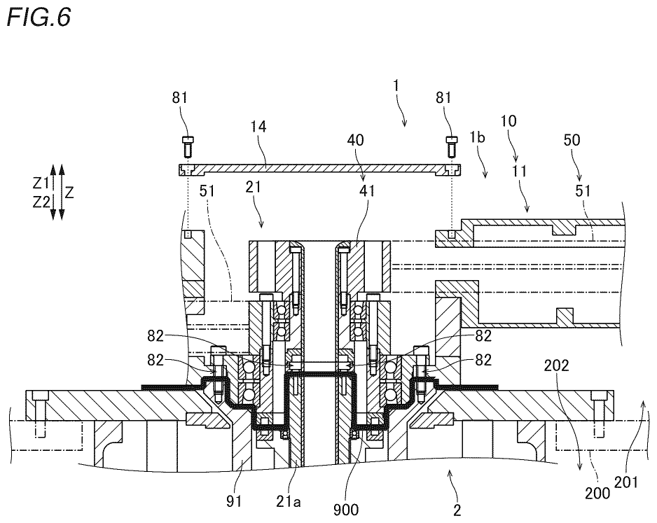

As shown in FIG. 6, the robot arm 1 can be attached to and detached from the base 2 with the pulley 40 and belt 50 integrated. Specifically, the robot arm 1 can be attached to and detached from the base 2 with the first joint-side pulley 41, the first arm inner belt 51, the second joint-side lower pulley 42a, the second joint-side upper pulley 42b, the second arm inner belt 52, and the third joint-side pulley 43 integrated. In FIG. 6, a boundary line 900 indicating a boundary for attachment and detachment of the robot arm 1 to and from the base 2 is schematically illustrated.

The robot arm 1 includes a cover 14 that is attachable to and detachable from the robot arm 1. Specifically, the cover 14 is attached to an upper proximal portion of the first arm unit 11 so as to be removable from the first arm unit 11 to the Z1 side. The cover 14 is attached to the upper proximal portion of the first arm unit 11 by fasteners 81. In a state in which the cover 14 is removed from the first arm unit 11, fasteners 82 for attaching the robot arm 1 to the base 2 are accessible from the Z1 side of the first arm unit 11.

When the robot arm 1 is removed from the base 2, first, the fasteners 81 are removed from the proximal portion of the first arm unit 11, and the cover 14 is removed from the proximal portion of the first arm unit 11. When the cover 14 is removed from the proximal portion of the first arm unit 11, the fasteners 82 become accessible from the Z1 side of the first arm unit 11. Then, when the fasteners 82 are removed from the robot arm 1 and the base 2, the entire portion of the robot arm 1 on the Z1 side with respect to the boundary line 900 becomes removable from the base 2. At this time, the entire portion of the robot arm 1 on the Z1 side with respect to the boundary line 900 can be removed from the base 2 while the states of the pulley 40 and the belt 50 are maintained. Thus, when the robot arm 1 is replaced due to a malfunction or when the robot arm 1 is initially attached to the base 2, the robot arm 1 can be attached to the base 2 with the tension of the belt 50 already adjusted, and thus the need to adjust the tension of the belt 50 after the robot arm 1 is attached can be eliminated. When the robot arm 1 is attached to the base 2, the procedure is reversed from that for removing the robot arm 1 from the base 2.

### Advantages of Embodiment

According to this embodiment, the following advantages are achieved.

According to this embodiment, the drive 30 is configured to drive the plurality of arm units 10 connected to each other in conjunction with each other such that the robot arm 1 operates to move the hand H within the circular range in the horizontal plane. The interior 1b of the robot arm 1 is at atmospheric pressure. Accordingly, heat from the robot arm 1 can be dissipated through the air in the interior 1b of the robot arm 1. That is, in the robot arm 1 that operates to move the hand H within the circular range, the heat from the robot arm 1 can be dissipated without providing water cooling piping or the like in the interior 1b of the robot arm 1, unlike a case in which the interior 1b of the robot arm 1 is in a vacuum state. Consequently, the heat dissipation of the robot arm 1 that operates to move the hand H within the circular range can be improved while the complexity of the device configuration is reduced or prevented.

According to this embodiment, the robot 100 for use in a vacuum environment includes the base 2 in the space 202 outside the vacuum chamber 200 to support the robot arm 1. In addition to the interior 1b of the robot arm 1, the interior 2a of the base 2 is at atmospheric pressure. Accordingly, heat from the robot arm 1 can be dissipated to the space 202 outside the vacuum chamber 200 through the air in the interior 1b of the robot arm 1 and the air in the base 2 provided in the space 202 outside the vacuum chamber 200 to support the robot arm 1.

According to this embodiment, the robot 100 for use in a vacuum environment includes the temperature sensor 5 as a sensor configured to detect the state of the robot arm 1. Accordingly, based on the state of the robot arm 1, such as the temperature of the interior 1b of the robot arm 1 detected by the temperature sensor 5, appropriate measures can be taken to improve the state of the robot arm 1.

According to this embodiment, the robot arm 1 includes the belt 50 in the interior 1b of the robot arm 1 to transmit the driving force of the drive 30 such that the plurality of arm units 10 connected to each other are driven in conjunction with each other by the drive 30. The belt 50 is made of a material having a thermal expansion coefficient different from the thermal expansion coefficients of the plurality of arm units 10. Accordingly, a material such as aluminum, which is relatively easy to mold and relatively lightweight, can be used for the plurality of arm units 10, and a material such as steel, which is highly durable, can be used for the belt 50. In other words, appropriate materials can be selected for the belt 50 and each of the plurality of arm units 10, and thus the degree of freedom in designing the robot arm 1 can be improved.

The robot 100 for use in a vacuum environment further includes the temperature sensor 5 in the interior 1b of the robot arm 1 to measure the temperature of the interior 1b of the robot arm 1. When the robot arm 1 and the belt 50 become hot due to a difference between the thermal expansion coefficient of the robot arm 1 and the thermal expansion coefficient of the belt 50, the operating accuracy of the robot arm 1 decreases. Therefore, by measuring the temperature of the interior 1b of the robot arm 1 with the temperature sensor 5, measures such as cooling the interior 1b of the robot arm 1 can be appropriately taken based on the measurement result of the temperature sensor 5 in order to reduce or prevent a decrease in the operating accuracy of the robot arm 1.

According to this embodiment, the robot 100 for use in a vacuum environment includes the controller 3 as a cooling controller configured or programmed to perform a control to cool the interior 1b of the robot arm 1 based on the measurement result of the temperature sensor 5. Accordingly, the interior 1b of the robot arm 1 is cooled such that a decrease in the operating accuracy of the robot arm 1 can be reduced or prevented.

According to this embodiment, the robot arm 1 includes the pulley 40 in the interior 1b of the robot arm 1 to transmit the driving force of the drive 30 together with the belt 50 such that the drive 30 causes the plurality of arm units 10 connected to each other to operate in conjunction with each other. The robot arm 1 further includes the rotating member 70 formed integrally with the pulley 40. The robot arm 1 further includes the seal 60 to provide a seal between the arm units 10 and the rotating member 70 to maintain the interior 1b of the robot arm 1 at atmospheric pressure. Accordingly, the seal 60 provides a seal between the rotating member 70, which is a rotating body, and the arm units 10, which are bodies to be rotated relative to the rotating member 70, such that the interior 1b of the robot arm 1, which is used in a vacuum environment, can be easily maintained at atmospheric pressure.

According to this embodiment, the seal 60 is fixed to the arm units 10 so as to rotate together with the arm units 10. Accordingly, the seal 60 can be easily arranged so as to provide a seal between the rotating member 70, which is a rotating body, and the arm units 10, which are bodies to be rotated relative to the rotating member 70.

According to this embodiment, the robot 100 for use in a vacuum environment includes the base 2 to support the robot arm 1. The plurality of arm units 10 include the first arm unit 11 supported by the base 2 and rotatable relative to the base 2 around the first rotation shaft 91 in the horizontal plane, and the second arm unit 12 supported by the first arm unit 11 and rotatable relative to the first arm unit 11 around the second rotation shaft 92 different from the first rotation shaft 91 in the horizontal plane. The pulley 40 includes the second joint-side lower pulley 42a as the first pulley arranged in the interior 11a of the first arm unit 11 and around the second rotation shaft 92. The rotating member 70 includes the first rotating member 71 formed integrally with the second joint-side lower pulley 42a. The seal 60 includes the first seal 61 in the interior 11a of the first arm unit 11 to provide a seal between the first arm unit 11 and the first rotating member 71. Accordingly, the first seal 61 can provide a seal between the first rotating member 71, which is a rotating body, and the first arm unit 11, which is a body to be rotated relative to the first rotating member 71.

According to this embodiment, the plurality of arm units 10 include the hand unit 13 supported by the second arm unit 12, rotatable around the third rotation shaft 93 different from the first rotation shaft 91 and the second rotation shaft 92 in the horizontal plane, and to allow the hand H to be arranged thereon. The pulley 40 includes the third joint-side pulley 43 as the second pulley arranged in the interior 12a of the second arm unit 12 and around the third rotation shaft 93. The rotating member 70 includes the third rotation shaft 93 as the second rotating member formed integrally with the third joint-side pulley 43. The seal 60 includes the second seal 62 in the interior 12a of the second arm unit 12 to provide a seal between the second arm unit 12 and the third rotation shaft 93. Accordingly, the second seal 62 can provide a seal between the third rotation shaft 93, which is a rotating body, and the hand unit 13, which is a body to be rotated relative to the third rotation shaft 93.

### Modified Examples

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the first seal 61 and the second seal 62 are contact seals has been shown in the aforementioned embodiment, the present disclosure is not limited to this. In the present disclosure, the first seal may be a non-contact contactless seal, or the second seal may be a non-contact seal.

While the example in which the seal 60 is fixed to the arm units 10 so as to rotate together with the arm units 10 has been shown in the aforementioned embodiment, the present disclosure is not limited to this. In the present disclosure, the seal may be fixed to the rotating member fixed to the pulley so as to rotate with the pulley so as to rotate together with the rotating member.

While the example in which the controller 3, which controls the operation of the robot arm 1, performs a control to cool the interior 1b of the robot arm 1 has been shown in the aforementioned embodiment, the present disclosure is not limited to this. In the present disclosure, the robot for use in a vacuum environment may include a cooling controller that performs a control to cool the interior of the robot arm, separately from the controller that controls the operation of the robot arm.

While the example in which the robot 100 for use in a vacuum environment includes the controller 3 as the cooling controller that performs a control to cool the interior 1b of the robot arm 1 based on the measurement result of the temperature sensor 5 has been shown in the aforementioned embodiment, the present disclosure is not limited to this. In the present disclosure, the robot for use in a vacuum environment may include an operation correction controller that performs a control to correct the operation of the robot arm based on the measurement result of the temperature sensor. Correction of the operation of the robot arm includes, for example, correction of the placement position or pick-up position of the substrate, correction of the motion trajectory of the robot arm, correction of the motion speed of the robot arm, etc. Accordingly, by correcting the operation of the robot arm, a decrease in the operating accuracy of the robot arm can be reduced or prevented, similarly to the above embodiment.

While the example in which the robot 100 for use in a vacuum environment includes the temperature sensor 5 in the interior 1b of the robot arm 1 being at atmospheric pressure to measure the temperature of the interior 1b of the robot arm 1 has been shown in the aforementioned embodiment, the present disclosure is not limited to this. In the present disclosure, the robot for use in a vacuum environment may not include the temperature sensor in the interior of the robot arm being at atmospheric pressure to measure the temperature of the interior of the robot arm.

While the example in which the belt 50, which transmits the driving force of the drive 30 such that the drive 30 drives the plurality of arm units 10 connected to each other in conjunction with each other, is made of a material having a thermal expansion coefficient different from those of the plurality of arm units 10 has been shown in the aforementioned embodiment, the present disclosure is not limited to this. In the present disclosure, the belt that transmits the driving force of the drive such that the drive drives the plurality of arm units connected to each other in conjunction with each other may be made of a material having the same thermal expansion coefficient as the plurality of arm units.

While the example in which the robot 100 for use in a vacuum environment includes the temperature sensor 5 as the sensor configured to detect the state of the robot arm 1 has been shown in the aforementioned embodiment, the present disclosure is not limited to this. In the present disclosure, the robot for use in a vacuum environment may not include the sensor configured to detect the state of the robot arm. Alternatively, the robot for use in a vacuum environment may include a sensor configured to detect the state of the hand or a sensor configured to detect the state of the substrate supported by the hand.

While the example in which in addition to the interior 1b of the robot arm 1, the interior 2a of the base 2 is at atmospheric pressure has been shown in the aforementioned embodiment, the present disclosure is not limited to this. In the present disclosure, as long as the interior of the robot arm is at atmospheric pressure, the interior of the base may not be at atmospheric pressure.

While the example in which the robot 100 for use in a vacuum environment is a dual-arm robot including two robot arms 1 has been shown in the aforementioned embodiment, the present disclosure is not limited to this. In the present disclosure, the robot for use in a vacuum environment may include only one robot arm or may include three or more robot arms.

While the example in which the two robot arms 1 have similar structures to each other has been shown in the aforementioned embodiment, the present disclosure is not limited to this. In the present disclosure, the two robot arms 1 may have dissimilar structures to each other.

### Aspects

It will be appreciated by those skilled in the art that the exemplary embodiments described above are specific examples of the following aspects.

### Item 1

A robot for use in a vacuum environment, the robot comprising:
a hand to support a substrate;
a horizontal articulated robot arm to allow the hand to be attached thereto and including a plurality of arm units for use inside a vacuum chamber, the plurality of arm units being connected to each other; and
a drive to drive the robot arm; wherein
the drive is configured to drive the plurality of arm units connected to each other in conjunction with each other such that the robot arm operates to move the hand within a circular range in a horizontal plane; and
an interior of the robot arm is at atmospheric pressure.

### Item 2

The robot for use in a vacuum environment according to item 1, further comprising:
a base in a space outside the vacuum chamber to support the robot arm; wherein
in addition to the interior of the robot arm, an interior of the base is at atmospheric pressure.

### Item 3

The robot for use in a vacuum environment according to item 1 or 2, further comprising:
a sensor to detect at least one of a state of the hand, a state of the robot arm, or a state of the substrate supported by the hand.

### Item 4

The robot for use in a vacuum environment according to any one of items 1 to 3, wherein
the robot arm includes a belt in the interior of the robot arm to transmit a driving force of the drive such that the plurality of arm units connected to each other are driven in conjunction with each other by the drive; and
the belt is made of a material having a thermal expansion coefficient different from thermal expansion coefficients of the plurality of arm units.

### Item 5

The robot for use in a vacuum environment according to item 4, further comprising:
a temperature sensor in the interior of the robot arm to measure a temperature of the interior of the robot arm.

### Item 6

The robot for use in a vacuum environment according to item 5, further comprising:
a cooling controller configured or programmed to perform a control to cool the interior of the robot arm based on a measurement result of the temperature sensor.

### Item 7

The robot for use in a vacuum environment according to item 5, further comprising:
an operation correction controller configured or programmed to perform a control to correct operation of the robot arm based on a measurement result of the temperature sensor.

### Item 8

The robot for use in a vacuum environment according to any one of items 4 to 7, wherein the robot arm includes:
a pulley in the interior of the robot arm to transmit the driving force of the drive together with the belt such that the drive causes the plurality of arm units connected to each other to operate in conjunction with each other;
a rotating member formed integrally with the pulley; and
a seal to provide a seal between one of the plurality of arm units and the rotating member to maintain the interior of the robot arm at atmospheric pressure.

### Item 9

The robot for use in a vacuum environment according to item 8, wherein the seal is fixed to the arm unit so as to rotate together with the arm unit.

### Item 10

The robot for use in a vacuum environment according to item 8 or 9, further comprising:
a base to support the robot arm; wherein
the plurality of arm units include:
   a first arm unit supported by the base and rotatable relative to the base around a first rotation shaft in the horizontal plane; and
   a second arm unit supported by the first arm unit and rotatable relative to the first arm unit around a second rotation shaft different from the first rotation shaft in the horizontal plane;
the pulley includes a first pulley in an interior of the first arm unit and around the second rotation shaft;
the rotating member includes a first rotating member formed integrally with the first pulley; and
the seal includes a first seal to provide a seal between the first arm unit and the first rotating member.

### Item 11

The robot for use in a vacuum environment according to item 10, wherein
the plurality of arm units further include a hand unit supported by the second arm unit, rotatable around a third rotation shaft different from the first rotation shaft and the second rotation shaft in the horizontal plane, and to allow the hand to be attached thereto;
the pulley further includes a second pulley in an interior of the second arm unit and around the third rotation shaft;
the rotating member further includes a second rotating member as the third rotation shaft formed integrally with the second pulley; and
the seal further includes a second seal to provide a seal between the second arm unit and the second rotating member.

1. A robot for use in a vacuum environment, the robot comprising:
a hand to support a substrate;
a horizontal articulated robot arm to allow the hand to be attached thereto and including a plurality of arm units for use inside a vacuum chamber, the plurality of arm units being connected to each other; and
a drive to drive the robot arm; wherein
the drive is configured to drive the plurality of arm units connected to each other in conjunction with each other such that the robot arm operates to move the hand within a circular range in a horizontal plane; and
an interior of the robot arm is at atmospheric pressure.

2. The robot for use in a vacuum environment according to claim 1, further comprising:
a base in a space outside the vacuum chamber to support the robot arm; wherein
in addition to the interior of the robot arm, an interior of the base is at atmospheric pressure.

3. The robot for use in a vacuum environment according to claim 1, further comprising:
a sensor to detect at least one of a state of the hand, a state of the robot arm, or a state of the substrate supported by the hand.

4. The robot for use in a vacuum environment according to claim 1, wherein
the robot arm includes a belt in the interior of the robot arm to transmit a driving force of the drive such that the plurality of arm units connected to each other are driven in conjunction with each other by the drive; and
the belt is made of a material having a thermal expansion coefficient different from thermal expansion coefficients of the plurality of arm units.

5. The robot for use in a vacuum environment according to claim 4, further comprising:
a temperature sensor in the interior of the robot arm to measure a temperature of the interior of the robot arm.

6. The robot for use in a vacuum environment according to claim 5, further comprising:
a cooling controller configured or programmed to perform a control to cool the interior of the robot arm based on a measurement result of the temperature sensor.

7. The robot for use in a vacuum environment according to claim 5, further comprising:
an operation correction controller configured or programmed to perform a control to correct operation of the robot arm based on a measurement result of the temperature sensor.

8. The robot for use in a vacuum environment according to claim 4, wherein the robot arm includes:
a pulley in the interior of the robot arm to transmit the driving force of the drive together with the belt such that the drive causes the plurality of arm units connected to each other to operate in conjunction with each other;
a rotating member formed integrally with the pulley; and
a seal to provide a seal between one of the plurality of arm units and the rotating member to maintain the interior of the robot arm at atmospheric pressure.

9. The robot for use in a vacuum environment according to claim 8, wherein the seal is fixed to the arm unit so as to rotate together with the arm unit.

10. The robot for use in a vacuum environment according to claim 8, further comprising:
a base to support the robot arm; wherein
the plurality of arm units include:
a first arm unit supported by the base and rotatable relative to the base around a first rotation shaft in the horizontal plane; and
a second arm unit supported by the first arm unit and rotatable relative to the first arm unit around a second rotation shaft different from the first rotation shaft in the horizontal plane;
the pulley includes a first pulley in an interior of the first arm unit and around the second rotation shaft;
the rotating member includes a first rotating member formed integrally with the first pulley; and
the seal includes a first seal in the interior of the first arm unit to provide a seal between the first arm unit and the first rotating member.

11. The robot for use in a vacuum environment according to claim 10, wherein
the plurality of arm units further include a hand unit supported by the second arm unit, rotatable around a third rotation shaft different from the first rotation shaft and the second rotation shaft in the horizontal plane, and to allow the hand to be attached thereto;
the pulley further includes a second pulley in an interior of the second arm unit and around the third rotation shaft;
the rotating member further includes a second rotating member as the third rotation shaft formed integrally with the second pulley; and
the seal further includes a second seal to provide a seal between the second arm unit and the second rotating member.
